(19) United States
(12) Patent Application Publication
(10) Pub. No.: US 2021/0057386 A1
(43) Pub. Date: Feb. 25, 2021

(54) SEMICONDUCTOR DEVICE AND METHOD OF MANUFACTURING SEMICONDUCTOR DEVICE

(71) Applicant: SONY SEMICONDUCTOR SOLUTIONS CORPORATION, Kanagawa (JP)

(72) Inventor: Kenji TAKEO, Kanagawa (JP)

(73) Assignee: SONY SEMICONDUCTOR SOLUTIONS CORPORATION, Kanagawa (JP)

(21) Appl. No.: 16/964,663

(22) PCT Filed: Dec. 27, 2018
(86) PCT No.: PCT/JP2018/048382

§ 371 Date: Jul. 24, 2020

(30) Foreign Application Priority Data
Jan. 31, 2018 (JP) 2018-015355

(51) Int. Cl. H01L 25/065; H01L 21/3205; H01L 27/146

(52) U.S. Cl. CPC H01L 25/0657; H01L 27/146; H01L 21/3205

(57) ABSTRACT

To provide a semiconductor device and a method of manufacturing the semiconductor device capable of maintaining reliability even in a case where a structure is complicated. A semiconductor device includes at least one or more openings in a principal surface of a stacked layer structure, in which a planar shape of the opening in the principal surface includes an angular region protruding from the other region of the planar shape and including a bending point in an outer shape.

### TECHNICAL FIELD

The present disclosure relates to a semiconductor device and a method of manufacturing a semiconductor device.

### BACKGROUND ART

In recent years, semiconductor devices such as arithmetic processing devices, storage devices, and solid-state imaging devices formed using semiconductors such as silicon have become more and more complicated in structure. For example, in a semiconductor device, a stacked structure has been used, in which a plurality of substrates is bonded together and then a through electrode that penetrates one substrate is formed, thereby forming electrical connection among the plurality of substrates.

In a process of manufacturing a semiconductor device having a complicated structure, it may be necessary to form a hole or a slit having a high aspect ratio, which is more difficult to form. The hole or the slit having a high aspect ratio is likely to cause a defect in the semiconductor device because an etching time at the time of formation is likely to be long and embedding of a bottom with a resist or the like is likely to be uneven. Therefore, a technology for suppressing the influence occurring when forming a hole or a slit having a high aspect ratio is being studied.

For example, Patent Document 1 below discloses a technology of forming a through hole for a through electrode penetrating a substrate by providing a first hole having a tapered shape in which the diameter of the opening becomes narrower toward a bottom of the hole, and a cylindrical second hole formed in the bottom of the first hole.

### CITATION LIST

### Patent Document

Patent Document 1: Japanese Patent Application Laid-Open No. 2015-182969

### SUMMARY OF THE INVENTION

### Problems to be Solved by the Invention

However, in the technology disclosed in Patent Document 1, the first hole and the second hole are formed in separate processes, which therefore increases the cost of the process of manufacturing the semiconductor device. Furthermore, the through hole including the first hole and the second hole has more complicated shape and film configuration than a simple through hole that is vertically dug. Therefore, there is a possibility of a decrease in reliability in such a semiconductor device provided with the through hole including the first hole and the second hole.

Therefore, the present disclosure proposes a new and improved semiconductor device and a method of manufacturing the semiconductor device capable of maintaining reliability even in a case where a structure is complicated.

### Solutions to Problems

According to the present disclosure, there is provided a semiconductor device including at least one or more openings in a principal surface of a stacked layer structure, in which a planar shape of the opening in the principal surface includes an angular region protruding from the other region of the planar shape and including a bending point in an outer shape.

Furthermore, according to the present disclosure, there is provided a method of manufacturing a semiconductor device, the method including forming at least one or more openings in a principal surface of a stacked layer structure, the opening having a planar shape including an angular region including a bending point in an outer shape, the angular region protruding from the other region of the planar shape.

According to the present disclosure, the reliability of the semiconductor device can be maintained even in the case where the structure is complicated by suppressing, with a simpler structure, occurrence of defects due to the opening formed in the principal surface of the layer structure of the semiconductor device.

### Effects of the Invention

As described above, according to the present disclosure, it is possible to provide a semiconductor device capable of maintaining reliability even in a case where a structure is complicated.

Note that the above-described effect is not necessarily limited, and any of effects described in the present specification or another effect that can be grasped from the present specification may be exerted in addition to or in place of the above-described effect.

### BRIEF DESCRIPTION OF DRAWINGS

FIG. 1A is a plan view and a cross-sectional view illustrating an example of a shape of an opening provided in a semiconductor device according to a first embodiment of the present disclosure.

FIG. 1B is a plan view and a cross-sectional view illustrating another example of the shape of the opening provided in the semiconductor device according to the first embodiment of the present disclosure.

FIG. 2 is a plan view and a cross-sectional view illustrating an example of a shape of an opening provided in a semiconductor device according to a comparative example.

FIG. 3 is a perspective view for schematically describing a configuration of a semiconductor device according to a second embodiment of the present disclosure.

FIG. 4 is a schematic view illustrating a region where an opening to which the technology according to the present disclosure is applied is formed in a solid-state imaging device illustrated in FIG. 3.

FIG. 5A is a plan view illustrating an example of a shape of an opening provided in the semiconductor device according to the second embodiment.

FIG. 5B is a plan view illustrating an example of the shape of the opening provided in the semiconductor device according to the second embodiment.

FIG. 5C is a plan view illustrating an example of the shape of the opening provided in the semiconductor device according to the second embodiment.

FIG. 5D is a plan view illustrating an example of the shape of the opening provided in the semiconductor device according to the second embodiment.

FIG. 6A is a cross-sectional view illustrating an example of the shape of the opening provided in the semiconductor device according to the second embodiment.

FIG. 6B is a cross-sectional view illustrating an example of the shape of the opening provided in the semiconductor device according to the second embodiment.

FIG. 7 is a plan view illustrating an example of a shape of an opening provided in a semiconductor device according to a third embodiment of the present disclosure.

FIG. 8A is a cross-sectional view illustrating an example of the shape of the opening provided in the semiconductor device according to the third embodiment.

FIG. 8B is a cross-sectional view illustrating an example of the shape of the opening provided in the semiconductor device according to the third embodiment.

FIG. 9A is a plan view illustrating an example of the shape of the opening provided in the semiconductor device according to the third embodiment.

FIG. 9B is a plan view illustrating an example of the shape of the opening provided in the semiconductor device according to the third embodiment.

FIG. 9C is a plan view illustrating an example of the shape of the opening provided in the semiconductor device according to the third embodiment.

FIG. 9D is a plan view illustrating an example of the shape of the opening provided in the semiconductor device according to the third embodiment.

### MODE FOR CARRYING OUT THE INVENTION

Favorable embodiments of the present disclosure will be described in detail with reference to the appended drawings. Note that, in the present specification and drawings, redundant description of configuration elements having substantially the same functional configuration is omitted by providing the same sign.

Note that the description will be given in the following order.

1. First Embodiment

2. Second Embodiment
2.1. Configuration of Semiconductor Device
2.2. Configuration of Opening

3. Third Embodiment

4. Fourth Embodiment

### 1. First Embodiment

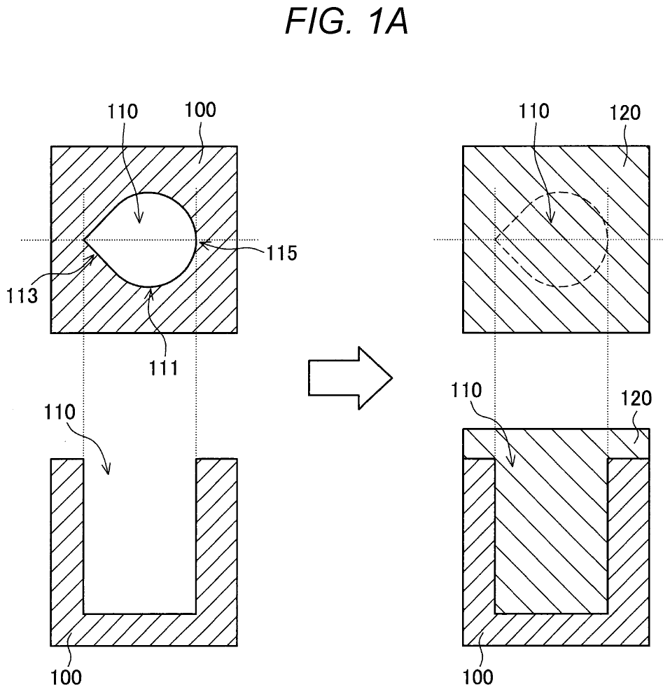

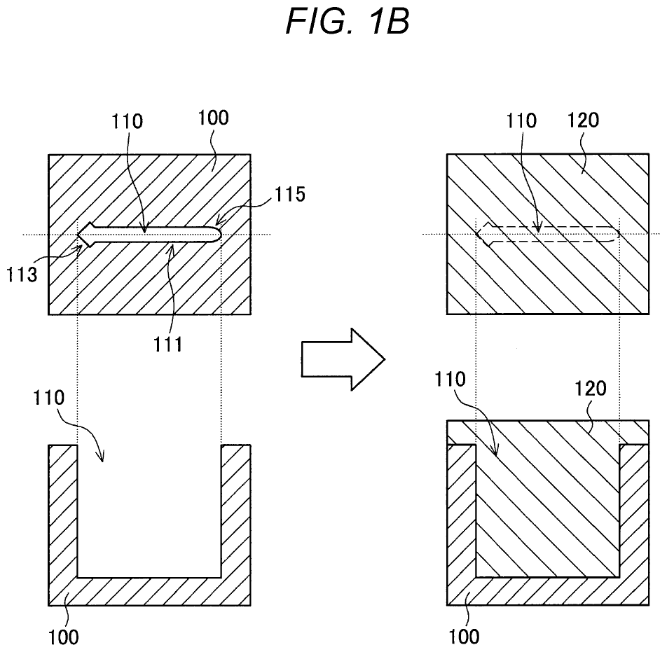

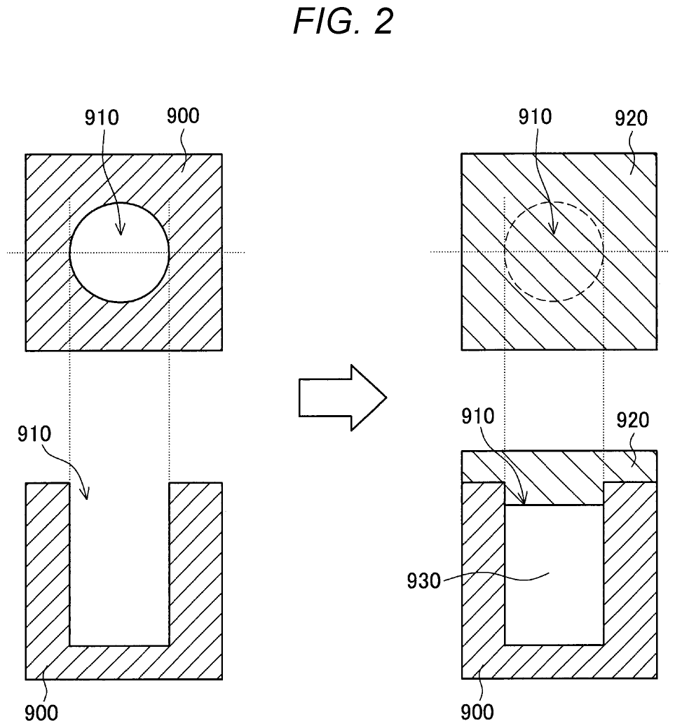

First, a configuration of a semiconductor device according to a first embodiment of the present disclosure will be described with reference to FIGS. 1A and 1B and FIG. 2.

Although not illustrated, the semiconductor device according to the present embodiment includes a semiconductor substrate, various elements provided on the semiconductor substrate, a plurality of insulating layers stacked on the semiconductor substrate, and various wirings provided inside the plurality of insulating layers and for electrically connecting the various elements, for example.

The insulating layer is formed using an insulating material and is provided as a stacked layer structure including a plurality of layers formed on the semiconductor substrate. The various wirings are formed using a conductive material and are provided to be embedded inside the insulating layers. The various wirings provided inside the insulating layers are electrically connected to one another by an interlayer electrode provided to penetrate the insulating layers. Furthermore, in a case where the semiconductor device is provided as a stacked semiconductor device in which a plurality of semiconductor substrates is stacked, the semiconductor substrates are provided with an inter-substrate electrode penetrating the semiconductor substrates to electrically connect the various elements or wirings provided in the respective stacked semiconductor substrates.

In such a semiconductor device, the insulating layers or the semiconductor substrates may have an opening in order to form the electrode or the various wirings or to isolate a predetermined region from the other region. However, in a case where the opening has a shape with a high aspect ratio such that a width is small and a depth is large, the opening provided in the insulating layer or the semiconductor substrate may influence the reliability of the semiconductor device, as will be described below.

Here, an influence of an opening on the reliability of a semiconductor device according to a comparative example will be described with reference to FIG. 2. FIG. 2 is a plan view and a cross-sectional view illustrating an example of a shape of an opening provided in a semiconductor device according to a comparative example. In FIG. 2, a state before application of a viscous fluid is illustrated on the left side in FIG. 2 and a state after application of the viscous fluid is illustrated on the right side in FIG. 2.

As illustrated in FIG. 2, consider a case in which a viscous fluid 920 such as a resist is brought to flow onto a principal surface of a layer structure 900 provided with an opening 910.

In a case of causing the viscous fluid 920 to flow onto the principal surface of the layer structure 900 provided with the opening 910, the viscous fluid 920 flowing on the principal surface can have a behavior of one of flowing into an inside of the opening 910, flowing on the principal surface avoiding the opening 910, or passing through and flowing on the opening 910 without flowing into the inside of the opening 910.

Therefore, to cause the viscous fluid 920 to flow into the opening 910 up to a bottom, it is important to cause the viscous fluid 920 to preferentially flow into the opening 910 and pushing out the air inside the opening 910 using the viscous fluid 920. In particular, to embed the entire opening 910 with the viscous fluid 120 without a gap, it is important to produce a state where the viscous fluid 920 preferentially flows into the opening 910 by controlling a physical phenomenon on an interface of the viscous fluid 920 and the air and a contact surface of the opening 910.

However, the opening 910 provided in the layer structure 900 illustrated in FIG. 2 has an isotropic circular planar shape on the principal surface. Therefore, in the opening 910 having such a planar shape, pressure when the viscous fluid 920 flows is dispersed around the opening 910.

Therefore, in FIG. 2, the viscous fluid 920 has a higher possibility of flowing on the principal surface avoiding the opening 910 or passing and flowing on the opening 910 without flowing into the opening 910 than a possibility of flowing into the opening 910. In such a case, the viscous fluid 920 blocks an upper portion of the opening 910 before embedding the entire opening 910 without a gap, and thus seals a path through which the air inside the opening 910 escapes. Therefore, the viscous fluid 920 blocks the upper portion of the opening 910 while leaving a void 930 inside the opening 910.

In the case where the void 930 exists inside the opening 910, there is a possibility that internal pressure of the void 930 rises due to expansion of the air in the void 930 due to heat treatment or the like in a subsequent stage of a manufacturing process, and cracks occur in the hardened viscous fluid 920 (a resist or the like) that covers the upper portion of the opening 910 or unintended stress is applied to the layer structure 900. Therefore, in the case where the large void 930 exists inside the opening 910, the reliability of the semiconductor device may be reduced.

The technology according to the present disclosure has been conceived by considering the above circumstances. The semiconductor device according to the present embodiment can promote a viscous fluid such as a resist to flow into an opening provided in a principal surface of a layer structure by providing the opening in a planar shape provided with an angular region into which the viscous fluid easily flows. Hereinafter, a specific planar shape of an opening into which the viscous fluid easily flows will be described with reference to FIGS. 1A and 1B. Note that the opening provided in the principal surface of the layer structure may be used as a through electrode by being embedded with a conductive material containing a metal or a metal compound such as copper (Cu), aluminum (Al), titanium (Ti), tungsten (W), or tantalum (Ta) and, or may be used as an insulating layer by being embedded with an insulating material such as silicon oxide (SiOₓ), silicon nitride (SiNₓ), silicon oxynitride (SiON), or organic resin, or a void.

FIG. 1A is a plan view and a cross-sectional view illustrating an example of a shape of an opening provided in the semiconductor device according to the present embodiment and FIG. 1B is a plan view and a cross-sectional view illustrating another example of the shape of the opening provided in the semiconductor device according to the present embodiment. In FIGS. 1A and 1B, a state before application of a viscous fluid is illustrated on the left side in FIGS. 1A and 1B and a state after application of the viscous fluid is illustrated on the right side in FIGS. 1A and 1B.

As illustrated in FIGS. 1A and 1B, the semiconductor device according to the present embodiment includes an opening 110 in a principal surface of a stacked layer structure 100. The opening 110 is provided to protrude from the other region 111 and is provided in a planar shape including an angular region 113 including a bending point in an outer shape.

Specifically, as illustrated in FIG. 1A, the planar shape of the opening 110 may be a drop shape obtained by extending one point of an outer periphery of the circular shape outward such that the one point becomes a bending point. At this time, the region extended to protrude from the circular shape corresponds to the angular region 113. Furthermore, as illustrated in FIG. 1B, the planar shape of the opening 110 may be an arrow shape in one direction provided with an arrow head at one end of a line segment serving as a shaft. At this time, the region of the arrow head corresponds to the angular region 113. That is, the angular region 113 corresponds to a region including at least one or more bending points each serving as a vertex in the outer shape. For example, the angular region 113 can correspond to a shape obtained by cutting out a region including at least one or more vertexes from a polygonal shape.

By forming the opening 110 in such an anisotropic planar shape including the angular region 113, pressure caused when a viscous fluid 120 flows can be concentrated to the angular region 113. As a result, the viscous fluid 120 easily flows from the angular region 113 into the opening 110. Therefore, a possibility that the viscous fluid 120 flows on the principal surface avoiding the opening 110 or passes and flows on the opening 110 without flowing into the opening 110 is reduced. Therefore, since the opening 110 can be filled with the viscous fluid 120 in order from the bottom of the opening 110, the entire opening 110 can be embedded with the viscous fluid 120 without a gap before the viscous fluid 120 blocks an upper portion of the opening 110.

Furthermore, the planar shape of the opening 110 may include a curved region 115 including a curve in an outer shape on the other side opposite to a side where the angular region 113 is provided.

Specifically, in the case where the planar shape of the opening 110 is the drop shape, as illustrated in FIG. 1A, a part of the circular shape on the opposite side of the angular region 113 extended to protrude from the circular shape may correspond to the curved region 115 including a curve in the outer shape. Furthermore, in the case where the planar shape of the opening 110 is the arrow shape in one direction, as illustrated in FIG. 1B, a starting point of the arrow existing on the opposite side of the angular region 113 of the arrow head that is an end point of the arrow may correspond to a curved region 115 including the curve in the outer shape.

The opening 110 has the planar shape provided with the curved region 115 on the other side opposite to the one side where the angular region 113 is provided, thereby forming a path through which the air existing inside the opening 110 is pushed out by the viscous fluid 120 and escapes.

Specifically, since the isotropic outer shape of the curved region 115 disperses the pressure when the viscous fluid 120 flows, the viscous fluid 120 less easily flows into the opening 110 in the curved region 115. Therefore, by providing the curved region 115 in the planar shape of the opening 110, the opening 110 enables the viscous fluid 120 to selectively flow into the opening 110 from the angular region 113 and the air existing inside the opening 110 to selectively escape from the curved region 115. Therefore, the opening 110 having the planar shape including the angular region 113 and the curved region 115 can have the opening 110 stably embedded with the viscous fluid 120 without a gap.

The technology according to the present disclosure can be applied to any layer structure 100 and viscous fluid 120 regardless of, for example, the types of the layer structure 100 provided with the opening 110 and the viscous fluid 120 embedded in the opening 110.

Therefore, the above-described layer structure 100 represents one of layered members inside the semiconductor device. Specifically, the layer structure 100 is a layer or a substrate having a principal surface, and may be any one of known semiconductor substrate, glass substrate, or resin substrate, or known semiconductor layer, insulating layer, or conductor layer. For example, the layer structure 100 may be a semiconductor substrate or a semiconductor layer containing silicon, germanium, gallium arsenide (GaAs), indium gallium arsenide (InGaAs), gallium nitride (GaN), silicon carbide (SiC), or the like or may be an insulating layer containing silicon oxide (SiOₓ), silicon nitride (SiNₓ), silicon oxynitride (SiON), aluminum oxide (Al₂O₃), titanium oxide (TiO₂), ditantalum pentoxide (Ta₂O₅), hafnium oxide (HfO₂), zircon oxide (ZrO₂), ruthenium oxide (RuO₂), lanthanum oxide (La₂O₃), or the like.

Furthermore, the above-described viscous fluid 120 represents a known organic material or inorganic material that can be a fluid, for example. For example, the viscous fluid 120 may be one of various resists (or compositions in which the various resists are dissolved), organic resins having curability or plasticity by heat or light, inorganic glass such as spin-on-glass (SOG), or the like.

### 2. Second Embodiment

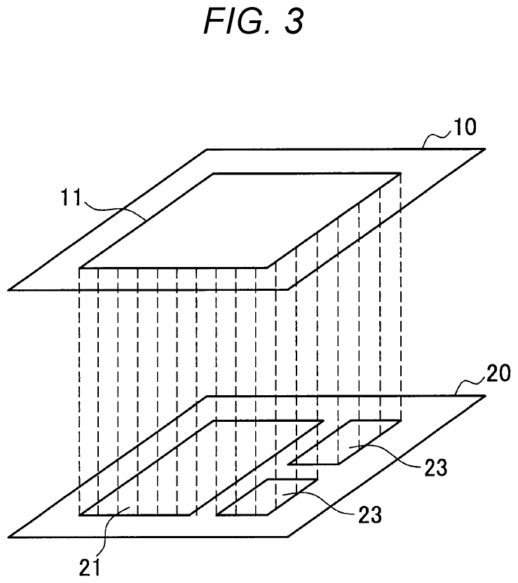

Next, a configuration of a semiconductor device according to a second embodiment of the present disclosure will be described with reference to FIG. 3 to FIGS. 6A and 6B.

(2.1. Configuration of Semiconductor Device)

First, a configuration of a semiconductor device according to the present embodiment will be described with reference to FIG. 3. FIG. 3 is a perspective view for schematically describing the configuration of the semiconductor device according to the second embodiment of the present disclosure.

As illustrated in FIG. 3, the semiconductor device according to the present embodiment is a stacked solid-state imaging device configured by stacking a first substrate 10 and a second substrate 20.

Specifically, the first substrate 10 includes a pixel region 11 provided with a photodiode (PD), and implements a function to photoelectrically convert light incident from a back surface side of the first substrate 10, using the PD of the pixel region 11. The second substrate 20 includes a control region 23 provided with a control circuit that processes a signal charge photoelectrically converted in the first substrate 10, a memory region 21 provided with a memory circuit that temporarily stores the signal charge photoelectrically converted in the first substrate 10, and the like. Thereby, the second substrate 20 implements a function to convert the signal charge photoelectrically converted in the first substrate 10 into an image signal. In the first substrate 10 and the second substrate 20, the circuits on the respective substrates can be more appropriately configured to correspond to the functions implemented by the respective substrates, whereby the solid-state imaging device can be more easily highly functionalized.

Note that the circuits provided in the first substrate 10 and the second substrate 20 are electrically connected to each other by an inter-substrate electrode provided penetrating the semiconductor substrate, either the first substrate 10 or the second substrate 20, for example. The inter-substrate electrode may be provided in a region surrounding a periphery of the pixel region 11, avoiding the pixel region 11, for example.

(2.2. Configuration of Opening)

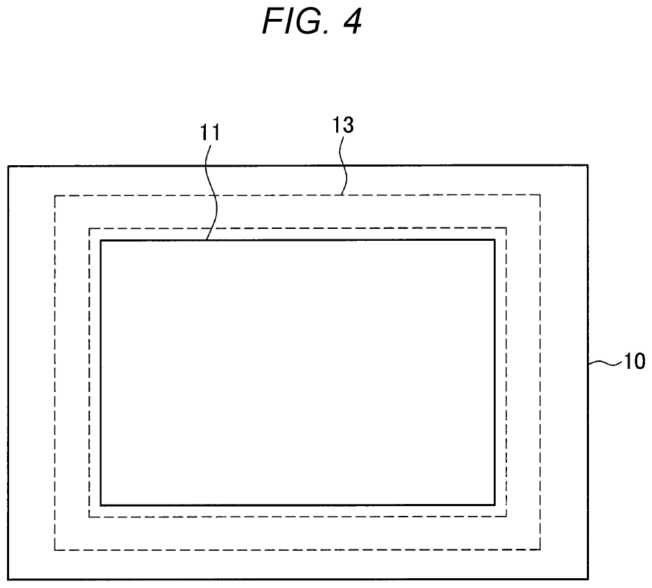

Next, shapes of openings provided in the semiconductor device according to the present embodiment will be described with reference to FIG. 4 to FIGS. 6A and 6B. FIG. 4 is a schematic view illustrating a region where an opening to which the technology according to the present disclosure is applied is formed in the solid-state imaging device illustrated in FIG. 3.

The opening to which the technology according to the present disclosure is applied may be provided in a peripheral region 13 around the pixel region 11 illustrated in FIG. 4, for example. Specifically, the peripheral region 13 around the pixel region 11 has a plurality of the inter-substrate electrodes for electrically connecting the circuits respectively provided in the first substrate 10 and the second substrate 20 at predetermined intervals. The technology according to the present disclosure may be applied to each of the openings for forming such inter-substrate electrodes.

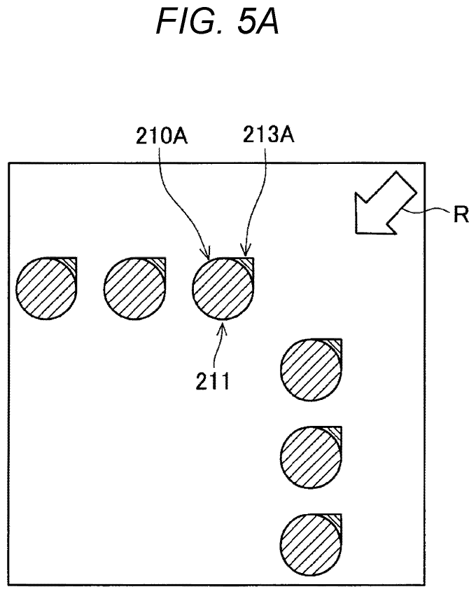

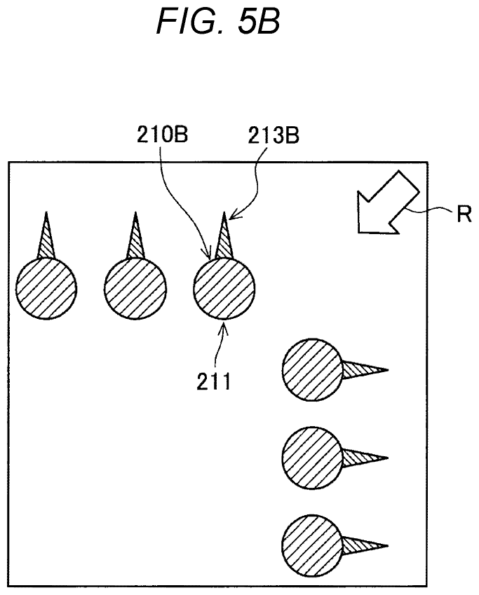

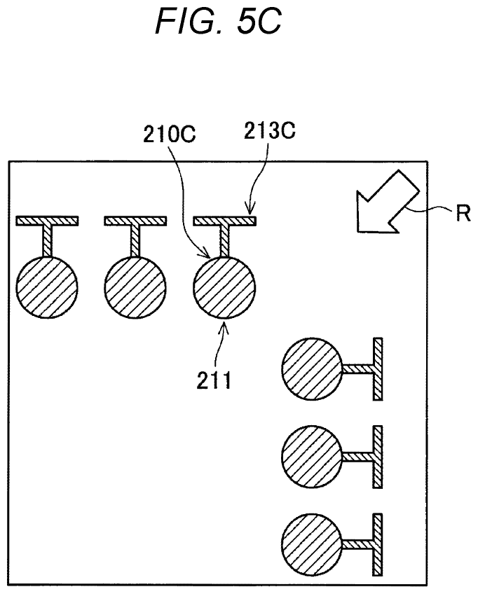

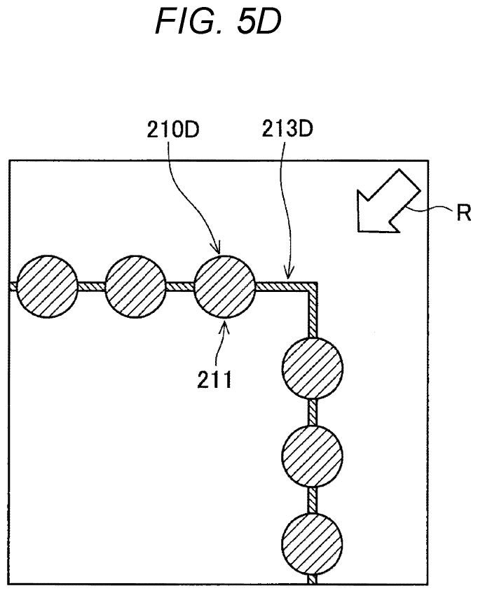

Next, planar shapes of the openings for forming the inter-substrate electrodes will be described with reference to FIGS. 5A to 5D. FIGS. 5A to 5D are plan views illustrating examples of shapes of the openings provided in the semiconductor device according to the present embodiment. Note that FIGS. 5A to 5D are schematic views illustrating an enlarged part of the peripheral region 13 near a vertex of the pixel region 11 in FIG. 4, and an arrow R indicates a direction into which a viscous fluid 120 flows.

For example, as illustrated in FIG. 5A, an opening 210A may be provided in a planar shape including a main region 211 in which the inter-substrate electrodes are formed, and an angular region 213A including a bending point in an outer shape and provided to protrude from the main region 211. Specifically, the opening 210A may have a drop shape obtained by extending one point of an outer periphery of the circular main region 211 outward such that the one point becomes the bending point. At this time, the region extended to protrude from the circular main region 211 corresponds to the angular region 213A.

Note that the angular region 213A may be provided on a principal surface of the first substrate 10 on a side opposite to a direction R into which the viscous fluid 120 such as a resist flows with respect to the main region 211. In other words, the angular region 213A may be provided on the principal surface of the first substrate 10 on an upstream side of the flow of the viscous fluid 120. In such a case, the opening 210A can have the angular region 213A arranged on the principal surface of the first substrate 10 in a direction from which the viscous fluid 120 flows in, the angular region 213A enabling the viscous fluid 120 to easily flow into the opening 210A. Therefore, the opening 210A can allow the viscous fluid 120 to easily flow thereto, thereby more reliably preventing formation of a void inside the opening 210A.

For example, as illustrated in FIG. 5B, an opening 210B may be provided in a planar shape including a main region 211 in which the inter-substrate electrodes are formed, and an angular region 213B including a bending point in an outer shape and provided to protrude from the main region 211. Specifically, the opening 210B may have a shape having a triangular angular region 213B protruding from a part of the outer periphery of the circular main region 211.

Note that the angular region 213B may be provided on a principal surface of the first substrate 10 on a side substantially opposite to a direction R into which the viscous fluid 120 such as a resist flows with respect to the main region 211. For example, the angular region 213B may be provided on the principal surface of the first substrate 10, toward an angular range expanded by 90 degrees to each side from the direction R into which the viscous fluid 120 such as a resist flows. In such a case, the opening 210B can have the angular region 213B arranged on the principal surface of the first substrate 10 on the side of the direction from which the viscous fluid 120 such as a resist flows in, the angular region 213B enabling the viscous fluid 120 to easily flow into the opening 210B. Therefore, the opening 210B can allow the viscous fluid 120 to easily flow thereto, thereby more reliably preventing formation of a void inside the opening 210B.

However, in a case where the direction R into which the viscous fluid 120 such as a resist flows is not fixed, the angular region 213B may be provided to face an opposite side to the side where the pixel region 11 is provided (that is, an outside of the first substrate 10). Since the viscous fluid 120 flows from the outside of the first substrate 10, the viscous fluid 120 can easily flow into the opening 210B without depending on the direction from which the viscous fluid 120 flows in by causing the angular region 213B to face the outside of the first substrate 10.

For example, as illustrated in FIG. 5C, an opening 210C may be provided in a planar shape including a main region 211 in which the inter-substrate electrodes are formed, and an angular region 213C including a bending point in an outer shape and provided to protrude from the main region 211. Specifically, the opening 210C may have a shape having a linear angular region 213C protruding from a part of the outer periphery of the circular main region 211, the linear angular region 213C branching from a middle.

The angular region 213C is provided in a linear or slit planar shape narrower than the main region 211. Since such an angular region 213C has a larger effective surface area than the main region 211, a surface tension acting on the viscous fluid 120 from the layer structure 100 is large. As a result, the capillary phenomenon occurs in the angular region 213C, a force of drawing the viscous fluid 120 into the opening 210C acts in a larger manner. Thereby, the angular region 213C can allow the viscous fluid 120 to more easily flow into the opening 210C in the main region 211, thereby suppressing formation of a void inside the opening 210C.

Note that the angular region 213C may be provided on a principal surface of the first substrate 10 on a side substantially opposite to a direction R into which the viscous fluid 120 such as a resist flows with respect to the main region 211, similarly to FIG. 5B. Even in such a case, the opening 210C can allow the viscous fluid 120 to easily flow thereto, thereby more reliably preventing formation of a void inside the opening 210C.

For example, as illustrated in FIG. 5D, an opening 210D may be provided in a planar shape including the main region 211 in which the inter-substrate electrodes are formed, and an angular region 213D connecting the main regions 211. Specifically, the opening 210D may have a shape including a linear angular region 213D protruding from a part of the outer periphery of the circular main region 211, and being connected with the main region 211 of an adjacent opening 210D. Note that, to connect the main regions 211 of the openings 210D, the angular region 213D has a bending point in the outer shape to connect the main regions 211 of the openings 210D arrayed in directions orthogonal to each other in the peripheral region 13 near a vertex of the pixel region 11.

The angular region 213D is provided in a linear or slit planar shape narrower than the main region 211, similarly to the angular region 213C illustrated in FIG. 5C. Since such an angular region 213D has a large surface tension acting on the viscous fluid 120 from the layer structure 100, similarly to the angular region 213C illustrated in FIG. 5C. Therefore, the angular region 213D can allow the viscous fluid 120 to more easily flow into the opening 210D in the main region 211 due to occurrence of the capillary phenomenon, thereby further suppressing formation of a void inside the opening 210D.

Furthermore, in a case where the viscous fluid 120 flows into one opening 210D, the angular region 213D can guide the viscous fluid 120 from the opening 210D to the adjacent opening 210D because the angular region 213D connects the openings 210D. In such a case, when the viscous fluid 120 flows into any of the plurality of openings 210D, the viscous fluid 120 flows into all of the openings 210D. Therefore, according to the openings 210D having such planar shapes, a situation where the viscous fluid 120 does not flow inside the opening 210D can be prevented in a part of the plurality of openings 210D.

Note that the openings 210D finally need to have planar shapes electrically isolated from and independent of one another because the inter-substrate electrodes are finally provided in the openings 210D. Therefore, the angular region 213D connecting the openings 210D may be eliminated, for example, by embedding an insulating material or by etching back in an entire surface in a subsequent step.

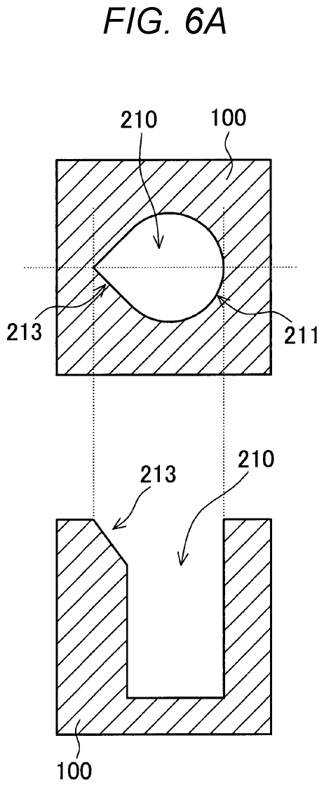

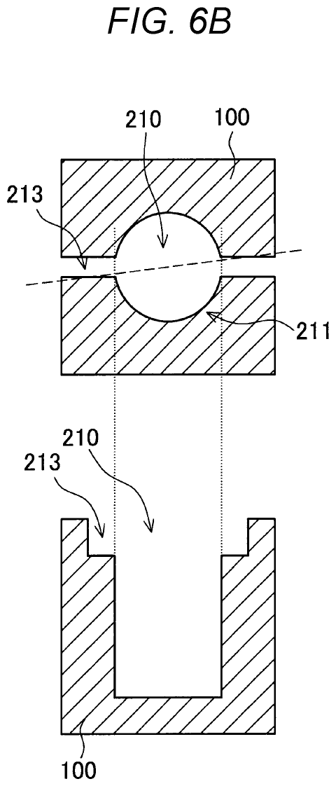

Next, cross-sectional shapes of the openings for forming the inter-substrate electrodes will be described with reference to FIGS. 6A and 6B. FIGS. 6A and 6B are cross-sectional views illustrating examples of shapes of the openings provided in the semiconductor device according to the present embodiment.

The cross-sectional shape of an opening 210 illustrated in FIG. 6A may correspond to the cross-sectional shape of the opening 210A illustrated in FIG. 5A, for example. Specifically, the opening 210 illustrated in FIG. 6A is provided in a principal surface of the layer structure 100 in a planar shape including the main region 211 in which the inter-substrate electrode is formed and an angular region 213 extended to protrude from the circular main region 211.

At this time, the opening 210 of the angular region 213 may be provided to have a shallow formation depth with respect to the opening 210 of the main region 211. Specifically, the opening 210 of the angular region 213 may be provided in a tapered shape in which the formation depth becomes gradually larger in a direction from the bending point of the outer shape toward the center of the main region 211. In the case where the opening 210 of the angular region 213 is provided in such a tapered shape, the surface area of the angular region 213 becomes large and thus the effective contact angle in the angular region 213 is reduced, so that the force of drawing the viscous fluid 120 into the inside of the angular region 213 can be increased. Therefore, the opening 210 having such a cross-sectional shape can allow the viscous fluid 120 to more easily flow thereto, thereby further suppressing formation of a void inside the opening 210.

Note that the opening 210 having the cross-sectional shape illustrated in FIG. 6A can be formed by dry etching the layer structure 100. In the dry etching, an etching gas less easily enters a region where a pattern shape to be etched is narrow or small, and thus such a region is less easily etched than a region where the pattern shape to be etched is wide. Therefore, by forming the opening 210 by the dry etching, the cross-sectional shape of the angular region 213 having a narrower planar shape than the main region 211 can be formed into the tapered shape as illustrated in FIG. 6A.

The cross-sectional shape of the opening 210 illustrated in FIG. 6B may correspond to the cross-sectional shape of the opening 210D illustrated in FIG. 5D, for example. Specifically, the opening 210 illustrated in FIG. 6B may be provided in the principal surface of the layer structure 100 having a planar shape including the main region 211 in which the inter-substrate electrodes are formed, and the angular region 213 connecting the main regions 211.

At this time, the opening 210 in the angular region 213 may be provided to have a shallower formation depth than the opening 210 in the main region 211. In the case where the opening 210 in the angular region 213 is provided with such a shallow formation depth, the openings 210 can be easily formed into the planar shapes electrically isolated from and independently of one another by eliminating the angular region 213 in a subsequent step. Specifically, in the subsequent step, the angular region 213 connecting the openings 210 can be easily polished and eliminated, for example, by etching back in the entire surface.

Note that the opening 210 having the cross-sectional shape illustrated in FIG. 6B can be formed by dry etching, similarly to the opening 210 having the cross-sectional shape illustrated in FIG. 6A. In the dry etching, a region having a narrow pattern shape is less easily etched than a region having a wide pattern shape due to the microloading effect, so that an etching depth becomes shallow. Therefore, by forming the opening 210 by the dry etching, the cross-sectional shape of the angular region 213 having a narrower planar shape than the main region 211 can be formed into the shape with the shallow formation depth as illustrated in FIG. 6B.

### 3. Third Embodiment

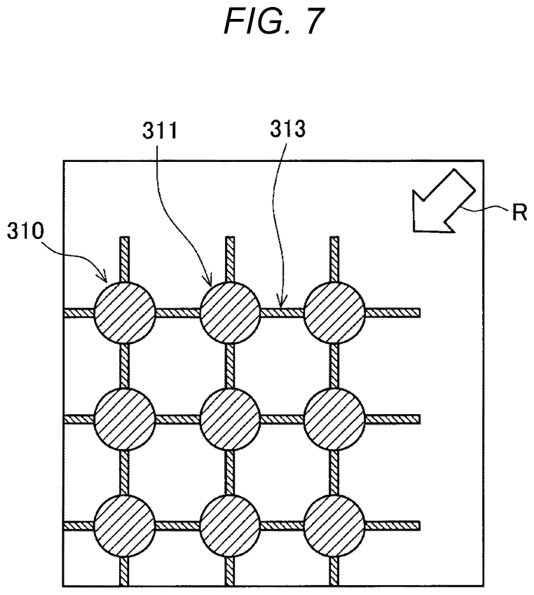

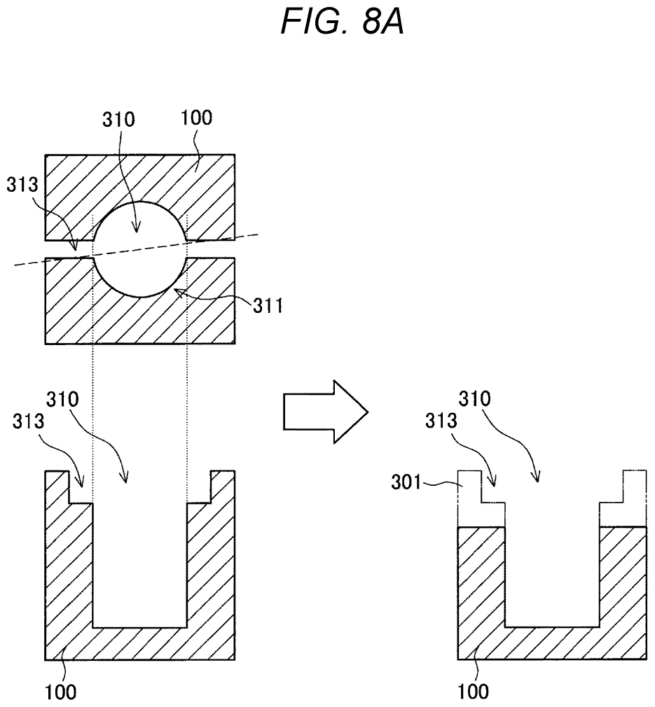

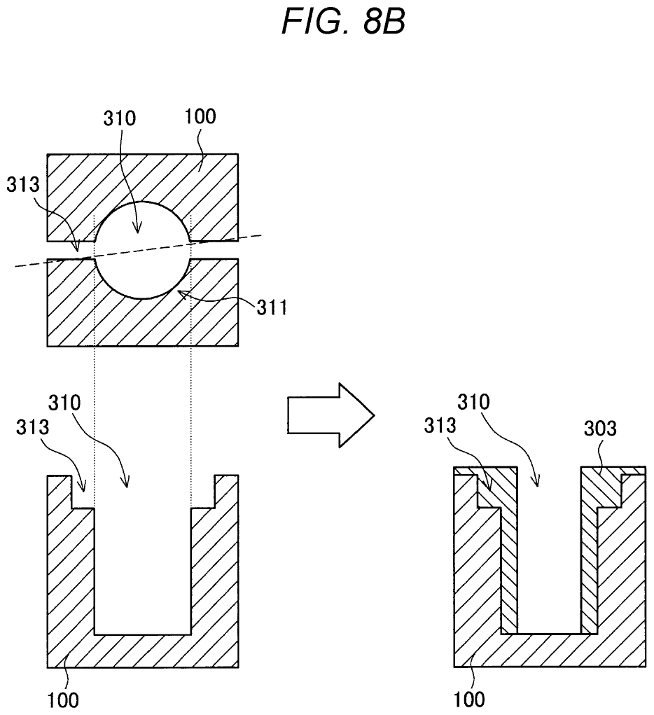

Next, a configuration of a semiconductor device according to a third embodiment of the present disclosure will be described with reference to FIG. 7 and FIGS. 8A and 8B.

The semiconductor device according to the third embodiment is a stacked solid-state imaging device illustrated in FIGS. 3 and 4, similarly to the second embodiment. In the semiconductor device according to the third embodiment, an opening to which the technology according to the present disclosure is applied may be provided inside a pixel region 11 illustrated in FIG. 4. Specifically, in the pixel region 11, a plurality of interlayer electrodes for transferring a signal charge photoelectrically converted in each pixel to a signal processing circuit is provided at predetermined intervals for each pixel or for each plurality of pixels. The technology according to the present disclosure may be applied to each of openings for forming such interlayer electrodes.

Here, planar shapes of the openings for forming the interlayer electrodes will be described with reference to FIG. 7. FIG. 7 is a plan view illustrating an example of a shape of the opening provided in the semiconductor device according to the present embodiment. Note that FIG. 7 is a schematic view illustrating an enlarged part of the pixel region 11 in FIG. 4, and an arrow R indicates a direction into which a viscous fluid 120 flows.

For example, as illustrated in FIG. 7, an opening 310 may be provided in a planar shape including a main region 311 in which the interlayer electrodes are formed, and an angular region 313 protruding from the main region 311 and connecting the main regions 311.

Specifically, the opening 310 may have a shape including an angular region 313 including a linear shape protruding from a part of an outer periphery of the circular main region 311, and a linear shape protruding from a part of the outer periphery of the circular main region 311 and being connected with the main region 311 of an adjacent opening 310. Note that the angular regions 313 may be arranged in a square lattice manner, for example, in order to connect the main regions 311 of the openings 310 arranged in a square lattice manner. Furthermore, in the openings 310 arranged on the outermost periphery of the tetragonal lattice manner, the angular region 313 may be provided to protrude from a part of the outer periphery of the main region 311.

The angular region 313 is provided in a linear or slit planar shape narrower than the main region 311. Since such an angular region 313 has a larger effective surface area than the main region 311, a surface tension acting on the viscous fluid 120 from a layer structure 100 is large. As a result, the capillary phenomenon occurs in the angular region 313, a force of drawing the viscous fluid 120 into the opening 310 acts in a larger manner. Thereby, the angular region 313 can allow the viscous fluid 120 to more easily flow into the opening 310 in the main region 311, thereby suppressing formation of a void inside the opening 310.

Furthermore, in a case where the viscous fluid 120 flows into one opening 310, the viscous fluid 120 can be guided from the opening 310 to the adjacent opening 310 using the angular region 313 because the angular region 313 connects the openings 310. In such a case, the viscous fluid 120 having flown into the angular region 313 can be guided to the inside of the openings 310 of all the main regions 311 connected by the angular region 313. Therefore, according to the openings 310 having such planar shapes, a situation where the viscous fluid 120 does not flow inside the opening 310 can be prevented in a part of the plurality of openings 310.

Next, each cross-sectional shape of the openings for forming the interlayer electrodes will be described with reference to FIGS. 8A and 8B. FIGS. 8A and 8B are cross-sectional views illustrating an example of a shape of an opening provided in the semiconductor device according to the present embodiment. In FIGS. 8A and 8B, a state of a cross-sectional view of the opening before application of a viscous fluid is illustrated on the left side in FIGS. 8A and 8B and a final state of the cross-sectional view of the opening is illustrated on the right side in FIGS. 8A and 8B.

The opening 310 illustrated in FIGS. 8A and 8B may be provided in a planar shape including the main region 311 in which interlayer electrodes are formed, and the angular region 313 protruding from a part of the outer periphery of the circular main region 311, in a principal surface of the layer structure 100. The angular region 313 is provided in a linear shape connected with the main region 311 of the adjacent opening 310, and the opening 310 in the angular region 313 may be provided to have a shallower formation depth than the opening 310 in the main region 311.

At this time, as illustrated in FIG. 8A, a predetermined layer 301 provided with the opening 310 of the angular region 313 may be eliminated in a subsequent step. Thereby, the openings 310 can have planar shapes electrically isolated from and independently of one another, whereby the interlayer electrodes formed in the openings 310 can be electrically isolated from one another. The predetermined layer 301 provided with the opening 310 of the angular region 313 may be eliminated by etching back in the entire surface or chemical mechanical polishing (CMP), for example.

Furthermore, as illustrated in FIG. 8B, the opening 310 of the angular region 313 may be embedded with an insulating material 303 in a subsequent step. Thereby, the interlayer electrodes formed in the respective openings 310 can be electrically isolated from one another. Note that, needless to say, a part of the opening 310 of the main region 311 may be embedded with the insulating material 303. The embedding of the opening 310 of the angular region 313 with the insulating material may be performed by chemical vapor deposition (CVD) on a selective region using a mask, for example.

Note that the opening 310 having the cross-sectional shape illustrated in FIGS. 8A and 8B can be formed by dry etching the layer structure 100. In the dry etching, a region having a narrow pattern shape is less easily etched than a region having a wide pattern shape due to the microloading effect, so that an etching depth becomes shallow. Therefore, by forming the opening 310 by the dry etching, the cross-sectional shape of the angular region 313 having a narrower planar shape than the main region 311 can be formed into the shape with the shallow formation depth as illustrated in FIGS. 8A and 8B.

### 4. Fourth Embodiment

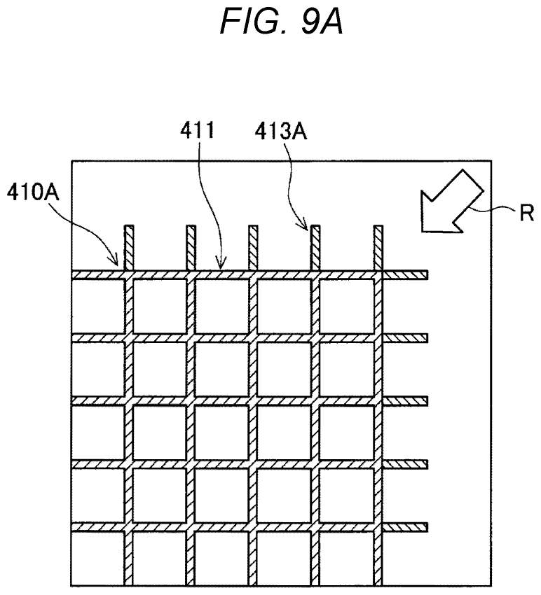

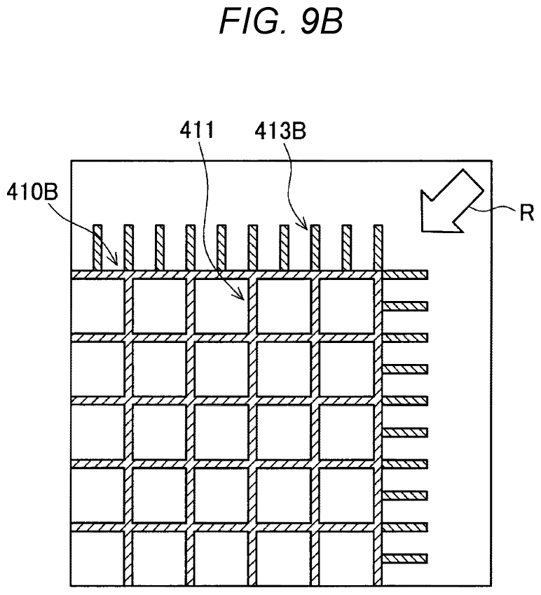

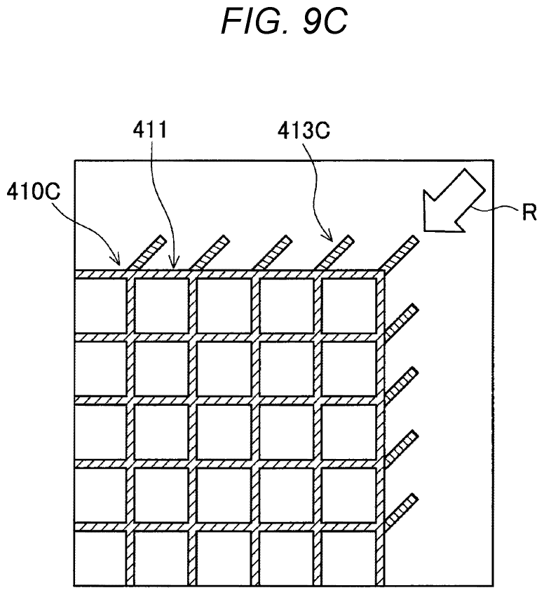

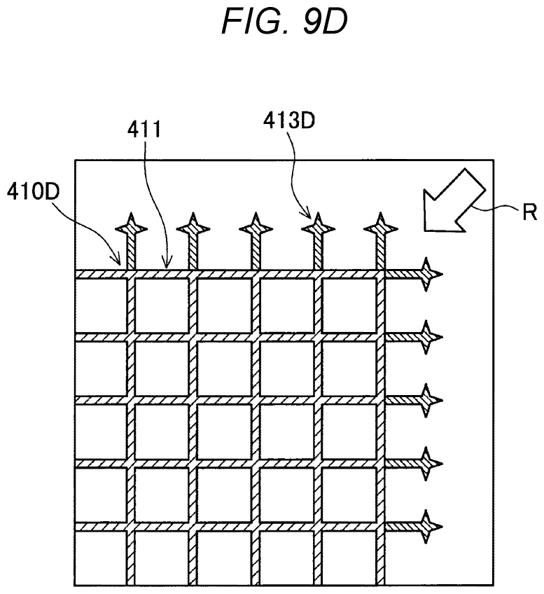

Next, a configuration of a semiconductor device according to a fourth embodiment of the present disclosure will be described with reference to FIGS. 9A and 9D.

The semiconductor device according to the fourth embodiment is a stacked solid-state imaging device illustrated in FIGS. 3 and 4, similarly to the second and third embodiments. In the semiconductor device according to the fourth embodiment, an opening to which the technology according to the present disclosure is applied may be provided inside a pixel region 11 illustrated in FIG. 4. Specifically, in the pixel region 11, a pixel separation layer that separates a region of a semiconductor substrate for each pixel is provided in a square lattice manner. The technology according to the present disclosure may be applied to each of the openings for forming such a pixel separation layer.

Here, planar shapes of the openings for forming a pixel separation layer will be described with reference to FIGS. 9A to 9D. FIGS. 9A to 9D are plan views illustrating an example of a shape of an opening provided in the semiconductor device according to the present embodiment. Note that FIGS. 9A to 9D are schematic views illustrating an enlarged part of the pixel region 11 in FIG. 4, and an arrow R indicates a direction into which a viscous fluid 120 flows.

For example, as illustrated in FIG. 9A, an opening 410A may be provided in a planar shape including a main region 411 in which the pixel separation layer is formed, and an angular region 413A provided to protrude outward from an outermost periphery of the main region 411. Specifically, the opening 410A may have a shape in which the linear angular region 413A protrudes at the same intervals as the main region 411 from the outermost periphery of the main region 411 arranged in the square lattice manner.

The angular region 413A is provided in a narrow linear or slit shape similar to the main region 411. Such a linear angular region 413A has a large surface tension acting on a viscous fluid 120 from a layer structure 100. Therefore, a force of drawing the viscous fluid 120 into the opening 410A acts in a large manner due to occurrence of the capillary phenomenon. Therefore, the angular region 413A can allow the viscous fluid 120 to more easily flow into the opening 410A, thereby suppressing formation of a void inside the opening 410A.

Furthermore, the angular region 413A is provided to face an opposite side (that is, an outside of a first substrate 10) to a side where the pixel region 11 is provided. According to this configuration, the angular region 413A can be arranged in a direction from which the viscous fluid 120 flows in, the angular region 413A enabling the viscous fluid 120 to easily flow into the opening 410A, with respect to the viscous fluid 120 flowing from the outside of the first substrate 10 (for example, from a direction R). Therefore, the angular region 413A enables the viscous fluid 120 to easily flow into the opening 210B.

For example, as illustrated in FIG. 9B, an opening 410B may be provided in a planar shape including the main region 411 in which the pixel separation layer is formed, and an angular region 413B provided to protrude outward from the outermost periphery of the main region 411. Specifically, the opening 410B may have a shape in which the linear angular region 413B protrudes at narrower intervals than the main region 411 from the outermost periphery of the main region 411 arranged in the square lattice manner.

The angular region 413B is provided in a narrow linear or slit shape similar to the main region 411.

Thereby, the angular region 413B can allow the viscous fluid 120 to more easily flow into the opening 410B, similarly to the angular region 413A illustrated in FIG. 9A, thereby suppressing formation of a void inside the opening 410B. Note that, since the angular region 413B is provided at narrower intervals than the angular region 413A illustrated in FIG. 9A, the angular region 413B enables the viscous fluid 120 to more easily flow into the opening 410B, thereby suppressing occurrence of a void inside the opening 410B.

For example, as illustrated in FIG. 9C, an opening 410C may be provided in a planar shape including the main region 411 in which the pixel separation layer is formed, and an angular region 413C provided to protrude outward from the outermost periphery of the main region 411.

Specifically, the opening 410C may have a shape in which the linear angular region 413C protrudes at the same intervals as the main region 411 and toward the direction R in which the viscous fluid 120 flows, from the outermost periphery of the main region 411 arranged in the square lattice manner.

The angular region 413C is provided in a narrow linear or slit shape similar to the main region 411. Thereby, the angular region 413C can allow the viscous fluid 120 to more easily flow into the opening 410C, similarly to the angular region 413A illustrated in FIG. 9A, thereby suppressing formation of a void inside the opening 410C. Furthermore, the opening 410C can have the angular region 413C arranged on the principal surface of the first substrate 10 in the direction from which the viscous fluid 120 flows in, the angular region 413C enabling the viscous fluid 120 to easily flow into the opening 410C. Therefore, the opening 410C can allow the viscous fluid 120 to easily flow thereto, thereby more reliably preventing formation of a void inside the opening 410C.

For example, as illustrated in FIG. 9D, an opening 410D may be provided in a planar shape including the main region 411 in which the pixel separation layer is formed, and an angular region 413D provided to protrude outward from the outermost periphery of the main region 411. Specifically, the opening 410D may have a shape in which the linear angular region 413D with a modified end protrudes at the same intervals as the main region 411 from the outermost periphery of the main region 411 arranged in the square lattice manner.

The angular region 413D is provided in a narrow linear or slit shape similar to the main region 411, and is provided in a planar shape having a cross-shaped narrow projection in the linear end. According to the planar shape, the angular region 413D has a larger effective surface area in the cross-shaped projection in the end and can have a larger surface tension acting on the viscous fluid 120 from the layer structure 100. As a result, the angular region 413D can strongly draw the viscous fluid 120 into the opening 410 due to the capillary phenomenon. Thereby, the angular region 413D can allow the viscous fluid 120 to more easily flow into the opening 410 in the main region 411, thereby further suppressing formation of a void inside the opening 410.

Although the favorable embodiment of the present disclosure has been described in detail with reference to the accompanying drawings, the technical scope of the present disclosure is not limited to such examples. It is obvious that persons having ordinary knowledge in the technical field of the present disclosure can conceive various changes and alterations within the scope of the technical idea described in the claims, and it is naturally understood that these changes and alterations belong to the technical scope of the present disclosure.

The planar shape of the opening provided in the layer structure of the semiconductor device according to the present embodiment is not limited to the above-described specific shapes. The planar shape of the opening provided in the layer structure of the semiconductor device may be appropriately replaced or changed within the scope of the technical idea described in claims.

Furthermore, the effects described in the present specification are merely illustrative or exemplary and are not restrictive. That is, the technology according to the present disclosure can exhibit other effects obvious to those skilled in the art from the description of the present specification together with or in place of the above-described effects.

Note that following configurations also belong to the technical scope of the present disclosure.

(1)

A semiconductor device including:

at least one or more openings in a principal surface of a stacked layer structure, in which

a planar shape of the opening in the principal surface includes an angular region protruding from the other region of the planar shape and including a bending point in an outer shape.

(2)

The semiconductor device according to (1), in which the planar shape of the opening in the principal surface further includes a curved region including a curve in the outer shape on the other side opposite to one side where the angular region is provided.

(3)

The semiconductor device according to (1) or (2), in which the angular region has a shape obtained by cutting a region including at least one or more vertexes from a polygonal shape.

(4)

The semiconductor device according to (1) or (2), in which the angular region has a linear shape extending, bending, or branching from a partial region of the planar shape.

(5)

The semiconductor device according to (4), in which

a plurality of the openings is provided in the principal surface, and

the planar shapes of the openings in the principal surface are connected with one another in the angular region.

(6)

The semiconductor device according to any one of (1) to (5), in which the opening in the angular region has a shallower opening depth than the opening in the other region of the planar shape.

(7)

The semiconductor device according to any one of (1) to (6), in which an inside of the opening is embedded with a conductive material.

(8)

The semiconductor device according to (7), in which

the semiconductor device is configured by stacking a plurality of substrates each having a predetermined function, and

the conductive material configures an inter-substrate electrode that electrically connects the plurality of substrates.

(9)

The semiconductor device according to (8), in which

the semiconductor device is a solid-state imaging device, and

the inter-substrate electrode is provided in a region surrounding a periphery of a pixel region of the solid-state imaging device.

(10)

The semiconductor device according to (7), in which the conductive material configures an interlayer electrode that electrically connects a plurality of wirings provided via the layer structure.

(11)

The semiconductor device according to (10), in which

the semiconductor device is a solid-state imaging device, and

the interlayer electrode is provided for each pixel or for each plurality of pixels in a pixel region of the solid-state imaging device.

(12)

The semiconductor device according to any one of (1) to (6), in which an inside of the opening is embedded with a void or an insulating material.

(13)

The semiconductor device according to (12), in which the planar shape of the opening in the principal surface is a lattice shape.

(14)

The semiconductor device according to (13), in which

the semiconductor device is a solid-state imaging device, and

the opening is provided to isolate pixels from one another in a pixel region of the solid-state imaging device.

(15)

A method of manufacturing a semiconductor device, the method including:

forming at least one or more openings in a principal surface of a stacked layer structure, the opening having a planar shape including an angular region including a bending point in an outer shape, the angular region protruding from the other region of the planar shape.

(16)

The method of manufacturing a semiconductor device according to (15), the method further including:

filling an inside of the opening with a viscous fluid by applying the viscous fluid on the principal surface of the layer structure in which the opening is formed.

(17)

The method of manufacturing a semiconductor device according to (16), the method further including:

patterning the viscous fluid; and

etching the layer structure using the patterned viscous fluid as a mask.

(18)

The method of manufacturing a semiconductor device according to (16) or (17), in which the angular region is formed on an upstream side of a direction in which the viscous fluid flows at the time of applying the viscous fluid.

(19)

The method of manufacturing a semiconductor device according to (17) or (18), the method further including:

polishing the layer structure from a side of the principal surface until the angular region of the opening is eliminated after etching the layer structure.

(20)

The method of manufacturing a semiconductor device according to (17) or (18), the method further including:

embedding the angular region of the opening with an insulating material after etching the layer structure.

### REFERENCE SIGNS LIST

10 First substrate
11 Pixel region
13 Peripheral region
20 Second substrate
21 Memory region
23 Control region
100 Layer structure
110, 210, 210A, 210B, 210C, 210D, 310, 410, 410A, 410B, 410C, 410D Opening
113, 213, 213A, 213B, 213C, 213D, 313, 413, 413A, 413B, 413C, 413D Angular region
115 Curved region
120 Viscous fluid
211, 311, 411 Main region

What is claimed is:

1. A semiconductor device comprising:
at least one or more openings in a principal surface of a stacked layer structure, wherein
a planar shape of the opening in the principal surface includes an angular region protruding from the other region of the planar shape and including a bending point in an outer shape.

2. The semiconductor device according to claim 1, wherein the planar shape of the opening in the principal surface further includes a curved region including a curve in the outer shape on the other side opposite to one side where the angular region is provided.

3. The semiconductor device according to claim 1, wherein the angular region has a shape obtained by cutting a region including at least one or more vertexes from a polygonal shape.

4. The semiconductor device according to claim 1, wherein the angular region has a linear shape extending, bending, or branching from a partial region of the planar shape.

5. The semiconductor device according to claim 4, wherein
a plurality of the openings is provided in the principal surface, and
the planar shapes of the openings in the principal surface are connected with one another in the angular region.

6. The semiconductor device according to claim 1, wherein the opening in the angular region has a shallower opening depth than the opening in the other region of the planar shape.

7. The semiconductor device according to claim 1, wherein an inside of the opening is embedded with a conductive material.

8. The semiconductor device according to claim 7, wherein
the semiconductor device is configured by stacking a plurality of substrates each having a predetermined function, and
the conductive material configures an inter-substrate electrode that electrically connects the plurality of substrates.

9. The semiconductor device according to claim 8, wherein
the semiconductor device is a solid-state imaging device, and
the inter-substrate electrode is provided in a region surrounding a periphery of a pixel region of the solid-state imaging device.

10. The semiconductor device according to claim 7, wherein the conductive material configures an interlayer electrode that electrically connects a plurality of wirings provided via the layer structure.

11. The semiconductor device according to claim 10, wherein
the semiconductor device is a solid-state imaging device, and
the interlayer electrode is provided for each pixel or for each plurality of pixels in a pixel region of the solid-state imaging device.

12. The semiconductor device according to claim 1, wherein an inside of the opening is embedded with a void or an insulating material.

13. The semiconductor device according to claim 12, wherein the planar shape of the opening in the principal surface is a lattice shape.

14. The semiconductor device according to claim 13, wherein
the semiconductor device is a solid-state imaging device, and
the opening is provided to isolate pixels from one another in a pixel region of the solid-state imaging device.

15. A method of manufacturing a semiconductor device, the method comprising:
forming at least one or more openings in a principal surface of a stacked layer structure, the opening having a planar shape including an angular region including a bending point in an outer shape, the angular region protruding from the other region of the planar shape.

16. The method of manufacturing a semiconductor device according to claim 15, the method further comprising:
filling an inside of the opening with a viscous fluid by applying the viscous fluid on the principal surface of the layer structure in which the opening is formed.

17. The method of manufacturing a semiconductor device according to claim 16, the method further comprising:
patterning the viscous fluid; and
etching the layer structure using the patterned viscous fluid as a mask.

18. The method of manufacturing a semiconductor device according to claim 16, wherein the angular region is formed on an upstream side of a direction in which the viscous fluid flows at the time of applying the viscous fluid.

19. The method of manufacturing a semiconductor device according to claim 17, the method further comprising:
polishing the layer structure from a side of the principal surface until the angular region of the opening is eliminated after etching the layer structure.

20. The method of manufacturing a semiconductor device according to claim 17, the method further comprising:
embedding the angular region of the opening with an insulating material after etching the layer structure.
